(19) United States
(12) Patent Application Publication
(10) Pub. No.: US 2025/0329391 A1
(43) Pub. Date: Oct. 23, 2025

(54) MANUAL DYNAMIC WORD LINE START VOLTAGE (MDWLSV) PREDICTION AND SELF-ADAPTING CACHE PROGRAM FOR MEMORY OPERATIONS

(71) Applicant: Micron Technology, Inc., Boise, ID (US)

(72) Inventors: Zhong Yu, Shanghai (CN); Wenjun Wu, Shanghai (CN); Feng Xu, Shanghai (CN); Shen Wu, Shanghai (CN)

(21) Appl. No.: 19/173,748

(22) Filed: Apr. 8, 2025

Related U.S. Application Data
(60) Provisional application No. 63/636,044, filed on Apr. 18, 2024.

(51) Int. Cl. G11C 16/10; G11C 16/08; G11C 16/32

(52) U.S. Cl. CPC G11C 16/102; G11C 16/08; G11C 16/32

(57) ABSTRACT

Methods, systems, and devices for manual dynamic word line start voltage (MDWLSV) prediction and a self-adapting cache program for memory operations are described. In some examples, a memory device may receive a sequence of write commands for a memory block, and the memory device may monitor an interval between two consecutive write commands in the sequence. The memory device may compare the interval to a threshold interval. The memory device may utilize a first programming mode associated with a combination of a set feature (SF) and a get feature (GF) for MDWLSV prediction if the interval exceeds the threshold. The memory device may utilize a second programming mode associated with the SF for MDWLSV prediction if the interval is less than the threshold. The described techniques may provide for the host device to transmit commands for MDWLSV prediction in advance by transmitting the MDWLSV commands via a previous write command.

### CROSS REFERENCE

The present Application for Patent claims priority to U.S. Patent Application No. 63/636,044 by Yu et al., entitled “MANUAL DYNAMIC WORD LINE START VOLTAGE (MDWLSV) PREDICTION AND SELF-ADAPTING CACHE PROGRAM FOR MEMORY OPERATIONS,” filed Apr. 18, 2024, which is assigned to the assignee hereof, and which is expressly incorporated by reference in its entirety herein.

### TECHNICAL FIELD

The following relates to one or more systems for memory, including manual dynamic word line start voltage (MDWLSV) prediction and a self-adapting cache program for memory operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports manual dynamic word line start voltage (MDWLSV) prediction and a self-adapting cache program for memory operations in accordance with examples as disclosed herein.

FIG. 2 shows an example of a system that supports MDWLSV prediction and a self-adapting cache program for memory operations in accordance with examples as disclosed herein.

FIG. 3 shows an example of a first programming mode that supports MDWLSV prediction and a self-adapting cache program for memory operations in accordance with examples as disclosed herein.

FIG. 4 shows an example of a second programming mode that supports MDWLSV prediction and a self-adapting cache program for memory operations in accordance with examples as disclosed herein.

FIG. 5 shows a block diagram of a memory system that supports MDWLSV prediction and a self-adapting cache program for memory operations in accordance with examples as disclosed herein.

FIGS. 6 and 7 show flowcharts illustrating a method or methods that support MDWLSV prediction and a self-adapting cache program for memory operations in accordance with examples as disclosed herein.

### DETAILED DESCRIPTION

Some memory systems may perform write operations on a plane-by-plane basis. In some cases, the write operations may incur latency from predicting and setting a starting word line voltage for respective write operations, transferring the write command and corresponding data, and programming the memory device. In some examples, the memory system may utilize a get feature (GF), a set feature (SF), or both, to identify a starting word line voltage to set the word line to for programming the word line. The GF and SF may be associated with manual dynamic word line start voltage (MDWLSV) prediction schemes. The GF may include utilizing a programming voltage from a previous write command to precharge the word line for a subsequent write operation, and may be associated with a non- cache program mode of the memory system. A cache programming mode may utilize the SF. The cache program mode and the non-cache program mode, along with the corresponding starting word line prediction schemes for each program mode, may have varying benefits for different queue depths (e.g., quantities of commands stored in a queue at the memory device). Techniques for improving latency across all queue depths may be beneficial.

Techniques described herein may support applying a different programming mode and corresponding MDWLSV prediction scheme in accordance with a queue depth. In some examples, the queue depth may correspond to a write command interval (e.g., a duration between two write commands without another intermediate write command between them). In some examples, the memory device may monitor the interval and utilize the non-cache program mode with a combination of the SF and the GF for MDWLSV prediction in accordance with a first programming mode if the interval is greater than the threshold. The memory device may utilize the cache program mode, as well as the SF for MDWLSV prediction if the interval is less than the threshold in accordance with a second programming mode. Additionally, or alternatively, the described techniques may provide for the host device to transmit commands for MDWLSV prediction in advance by transmitting the MDWLSV commands via a previous write command.

In addition to applicability in memory systems as described herein, techniques for MDWLSV prediction and a self-adapting cache program for memory operations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory program speeds, which may decrease processing or latency times, improve response times, or otherwise improve user experience, among other benefits.

In addition to applicability in memory systems as described herein, techniques for MDWLSV prediction and a self-adapting cache program for memory operations may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by dynamically adjusting word line voltages, which may extend the life of electronic devices and thereby reducing electronic waste, among other benefits.

Features of the disclosure are illustrated and described in the context of systems, devices, and circuits. Features of the disclosure are further illustrated and described in the context of first and second programming modes and flowcharts.

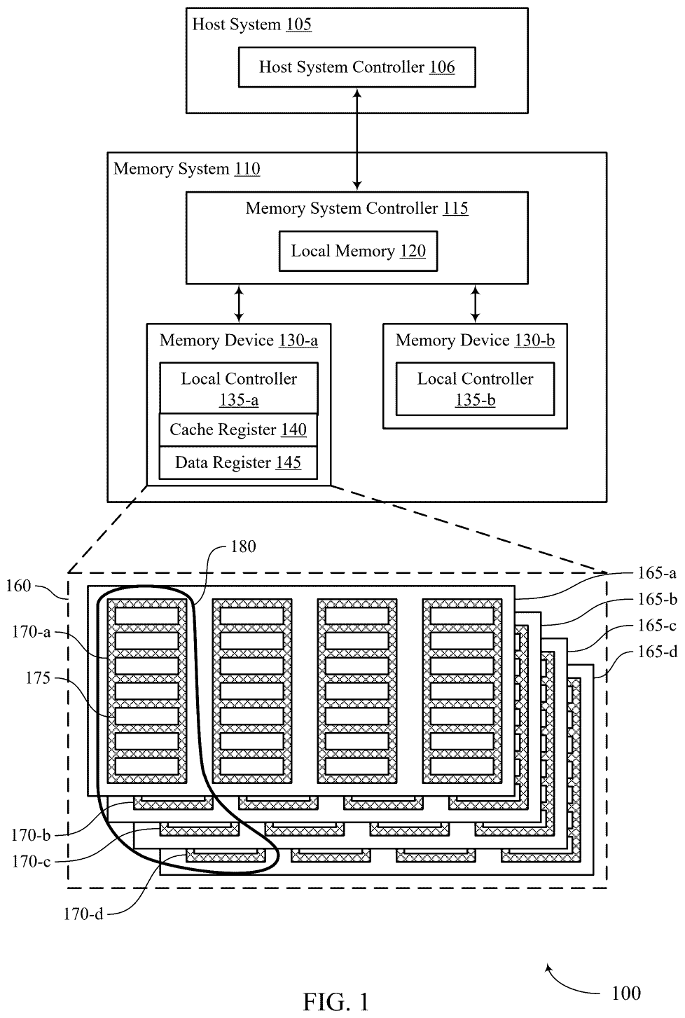

FIG. 1 shows an example of a system 100 that supports MDWLSV prediction and a self-adapting cache program for memory operations in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IOT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support MDWLSV prediction and a self-adapting cache program for memory operations. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

The memory system 110 may include a cache register 140 and a data register 145. In some cases, the cache register 140 and the data register 145 may be coupled with a local controller 135 and the die 160. In some examples, the host system 105, the memory system 110, or the memory device 130 may input data to the cache register 140 and move the data from the cache register to a block or plane address (e.g., specified in an access command) in the array of the die 160 according to a cache programming mode. In some aspects, the die 160 may indicate completion of the data transfer to the host system 105, the memory system 110, or the memory device 130 via a bit field indication (e.g., ARDY=1). Additionally, or alternatively, the host system 105, the memory system 110, or the memory device 130 may input data to the cache register 140, copy data from the cache register 140 to the data register 145, and transfer the data of the data register 145 to a block or plane address (e.g., specified in an access command) in the array of the die 160 according to a non-cache programming mode.

Some memory systems may perform write operations on a plane-by-plane basis. In some cases, the write operations may incur latency from predicting and setting a starting word line voltage for the write operation, transferring the write command and data, and programming the memory device. In some examples, the memory system 110 may utilize a GF, a SF, or both, to identify a starting word line voltage to set the word line to for programming the word line. The GF may include utilizing a programming voltage from a previous write command to precharge the word line for a subsequent write operation, and may be associated with the non-cache programming mode of the memory system 110. A cache programming mode may utilize the SF. The cache programming mode and the non-cache programming mode, along with the corresponding starting word line prediction schemes for each program mode, may have varying benefits for different queue depths (e.g., quantities of commands stored in a queue at the memory device). Techniques for improving latency across all queue depths may be beneficial.

As described herein, the memory system 110 may support applying a different programming mode and corresponding MDWLSV prediction scheme in accordance with a queue depth. In some examples, the queue depth may correspond to a write command interval (e.g., a duration between two write commands without another intermediate write command between them). In some examples, the memory device may monitor the interval and utilize the non-cache programming mode with a combination of the SF and the GF for MDWLSV prediction in accordance with a first programming mode if the interval is greater than the threshold. The memory device may utilize the cache programming mode, as well as the SF for MDWLSV prediction if the interval is less than the threshold in accordance with a second programming mode. Additionally, the host system 105 may transmit commands for MDWLSV prediction in advance by transmitting the MDWLSV commands via a previous write command.

The system 100 may include any quantity of non-transitory computer readable media that support MDWLSV prediction and a self-adapting cache program for memory operations. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

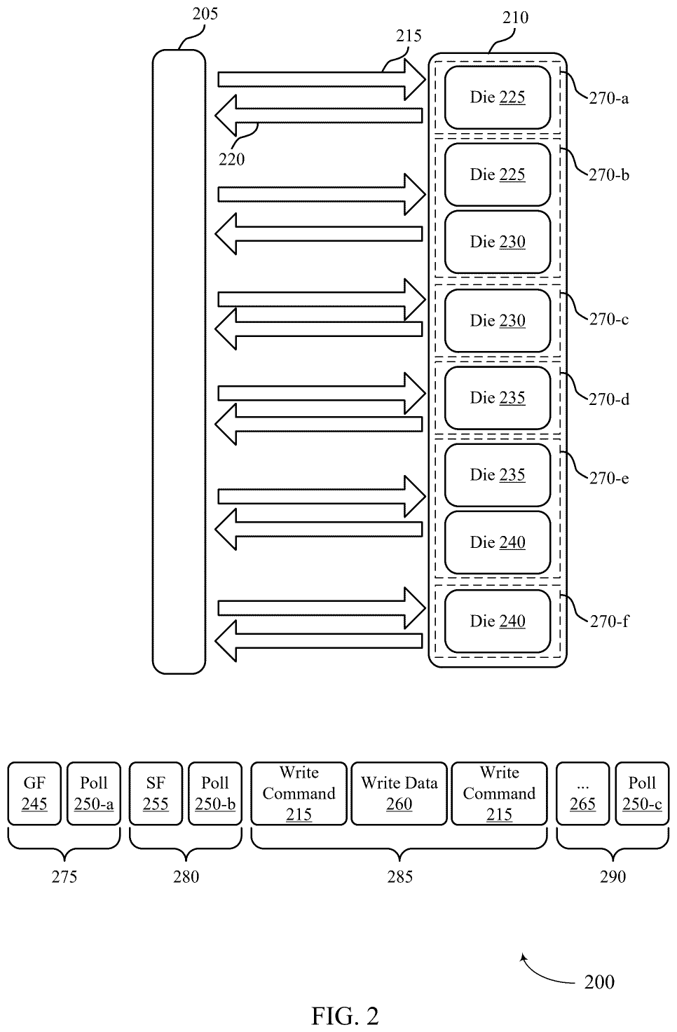

FIG. 2 shows an example of a system 200 that supports MDWLSV prediction and a self-adapting cache program for memory operations in accordance with examples as disclosed herein. The system 200 may be an example of a system 100 as described with reference to FIG. 1, or aspects thereof. The system 200 may include a memory system 210 configured to store data received from a host system 205 and to send data to the host system 205, if requested by the host system 205 using access commands (e.g., write commands 215). The system 200 may implement aspects of the system 100 as described with reference to FIG. 1. For example, the memory system 210 and the host system 205 may be examples of the memory system 110 and the host system 105, respectively, as described with reference to FIG. 1.

The memory system 210 may include one or more memory dies 225 through 240 to store data transferred between the memory system 210 and the host system 205 (e.g., in response to receiving access commands from the host system 205). The memory dies 225 through 240 may represent examples of the memory dies 160 as described with reference to FIG. 1. For example, the memory dies 225 through 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples. The memory dies 225 through 240 each may include one or more planes. For example, each of the memory dies 225 through 240 may respectively include six planes.

In some examples, the memory system 210 may operate in a force unit access (FUA) mode. Operating in the FUA mode may include receiving one or more write commands 215 indicating data to be written to non-volatile memory cells. For example, the memory system 210 may write data to one plane of a memory die at a time (e.g., one plane by one plane), which may include one or more non-volatile memory cells. In some examples, the memory system 210 may write four planes of data to a memory die for every 16 host commands (e.g., access commands). For example, the memory system 210 may write data to a first set of planes 270-a (e.g., four planes) in a first portion of the memory die 225 in response to receiving a set of write commands 215 (e.g., 16 write commands, or some other quantity). The memory system 210 may write data to a second set of planes 270-b in a second portion of the memory die 225 and a first portion of the memory die 230. For example, four of the six planes included in the memory die 225 may include data, and after receiving a set of write commands for the second set of planes 270-b, the memory system 210 may write data to the remaining two planes in the second portion of the memory die 225 and to the first portion of the memory die 230. The memory system 210 may continue to write data to the remaining sets of planes 270-c, 270-d, 270-e, and 270-f across the memory dies 230, 235, and 240, in response to (e.g., based on, according to, after receiving) respective write commands.

In some examples, the memory system 210 may transmit a response 220 to the host system 205 after completing the write command 215 (e.g., after reporting program done). The response 220 may indicate a completion of one or more write commands 215, an indication of a ready status (e.g., ARDY=1) to receive one or more additional write commands 215, among other examples. The host system 205 may transmit a next write command 215 to the memory system 210 after receiving the report. In some cases, the memory system 210 may not receive a sufficient quantity of write commands 215 to improve parallelism by a multiplane write operation.

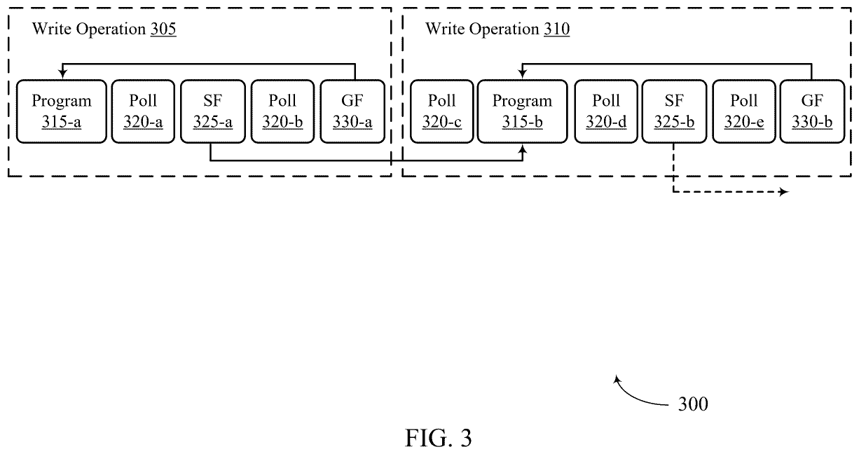

Each access command (e.g., write command 215) may be associated with a GF duration 275 (T_{gf}), an SF duration 280 (T_{sf}), a transfer write command and data duration 285 (T_{onfi_transfer}), and a programming duration 290 (T_{prog}). The GF duration 275 may include a GF 245 and a poll operation 250-a, described in greater detail elsewhere herein, including with reference to FIG. 3. In some examples, the SF duration 280 may include a SF 255 and a poll operation 250-b, also described in greater detail elsewhere herein, including with reference to FIG. 3. The transfer write command and data duration 285 may include one or more write commands 215 and a write data operation 260 that corresponds to transferring the one or more write commands 215 and data from a buffer of the memory system 210 to a memory block or plane indicated in the one or more write commands 215. In some examples, the programming duration 290 may include a duration to program data to a plane 265 and a poll operation 250-c.

In some examples, an MDWLSV operation may include the SF 255, the GF 245, or both. MDWLSV may support a reduction in the programming duration 290 by dynamically adjusting a programming start voltage according to previous programming operations. In some cases, the programming duration 290 for a memory device (e.g., a memory device 130) may be relatively high in response to a quantity of cycles (e.g., program/erase) the memory device has experienced. For example, if the memory device has a relatively low cycle quantity, the programming duration 290 may be relatively low and a higher start voltage may be used to perform the program operation.

The MDWLSV operation may store a word line start voltage for a partially programmed block using the GF 245. For example, the memory system 210 may write data to the planes in a first portion of the memory die 225 before receiving one or more write commands 215 to write data to planes in a portion of another memory die (e.g., memory die 230, memory die 235, or memory die 240. In this example, the word line start voltage for the memory die 225 may be stored using the GF 245. In some examples, the MDWLSV operation may charge the word line voltage according to the stored word line start voltage using the SF 255 if writing to the partially programmed block in the first portion of the memory die 225. For example, the memory system 210 may return to the memory die 225 to write the remaining planes (e.g., unprogrammed planes), retrieve the stored word line start voltage via the GF 245, and charge the word line according to the word line start voltage using the SF 255.

In some examples, one or more of the GF duration 275, the SF duration 280, the transfer write command and data duration 285, or the programming duration 290 may have a constant (e.g., fixed) duration. In some examples, the durations of the access command may be reduced by transmitting a MDWLSV operation (e.g., GF or SF) in advance of a next write command in a first programming mode. The first programming mode may be a non-cache programming mode that may support a reduced GF duration 275 and a reduced SF duration 280. Additionally, or alternatively, the durations of the access command may be reduced by performing the MDWLSV operation and the transfer write command and data duration 285 in a programming duration 290 of a previous write command in a second programming mode. The second programming mode may be a cache-programming mode.

In some examples, the first programming mode and the second programming mode may have different effects on duration optimization for different queue depths. For example, the memory system 210 may receive a sequence of write commands 215 for a memory block of a memory device. Queue depth may refer to the quantity of access commands received by the memory system 210, but not yet programmed to the memory block (e.g., commands stored in a queue or buffer at the memory system 210). For relatively high queue depths, the second programming mode (e.g., the cache program) may reduce the programming duration 290. For example, for a queue depth of five or more write commands 215, the programming duration 290 may be reduced in response to operating in the second programming mode. In some cases, such as for relatively low queue depths, the second programming mode may not reduce the programming duration 290. For example, the memory system 210 may receive a first write command 215 and a second write command 215 to a same memory die. In such examples, for relatively low queue depths, an interval duration between the first write command 215 and the second write command 215 may be longer than a sum of the transfer write command and data duration 285 and the programming duration 290. In such examples, the second programming mode may not support any reduction in duration of the programming duration 290. Thus, the first programming mode may be more beneficial than the second programming mode for relatively lower queue depths.

Techniques described herein provide for the system 200 to dynamically adjust a programming mode in accordance with the queue depth to reduce latency. That is, the system 200 may support MDWLSV prediction and a self-adapting cache program by applying the first programming operation or the second programming operation according to different interval durations, where the interval duration may correspond to the queue depth. For example, the memory system 210 may apply the second programming mode and MDWSLV prediction for queue depths that are greater than or equal to a threshold depth, and the memory system 210 may apply the first programming mode and MDWLSV prediction for queue depths that are less than the threshold depth.

The MDWLSV prediction may include performing the SF 255, the GF 245, or both in advance before receiving a next write command 215. In some cases, performing the SF 255 in advance may be referred to as SF prediction and performing the GF 245 may be referred to as GF prediction. In some examples, the GF prediction may retrieve a voltage of a previous write command, and the memory system 210 may not accept the command until ARDY=1. Thus, the GF prediction may disrupt a cache continuity if the interval between two write commands 215 is below a threshold interval.

In some examples, the memory system 210 may monitor a respective write command interval between each pair of two consecutive (e.g., write commands without another intermediate write command between them) write commands 215. For example, the memory system 210 may monitor the interval of two write commands 215 in the same die and same block (e.g., die 225-a and die 225-b). In some cases, the interval may correspond to a time period between a first write command 215 and a second write command 215 of a sequence of write commands 215 to the same die and the same block, where the second write command 215 may be consecutive to the first write command 215 in the sequence of write commands 215. As described herein, the interval may correspond to (e.g., be based on) a queue depth of commands at the memory system 210.

In some examples, the memory system 210 may compare the write command interval with a threshold interval in response to monitoring the write command interval. If the interval duration exceeds the threshold (e.g., is greater than or equal to the threshold interval duration), the memory system 210 may operate in the first programming mode. For example, the memory system 210 may predict the starting word line voltage for a next write operation corresponding to a next write command according to the SF 255 and a retrieval of the starting word line voltage in response to a previous write command according to the GF 245. If the interval duration is less than the threshold interval duration, the memory system 210 may operate in the second programming mode. For example, the memory system 210 may predict the starting word line voltage for the next write operation corresponding to the next write command. In some examples, the threshold duration may be equivalent to a sum of the transfer write and data duration 285 and the programming duration 290, or may be some other threshold (e.g., Th_{cache}).

FIG. 3 shows an example of a first programming mode 300 that supports MDWLSV prediction and a self-adapting cache program for memory operations in accordance with examples as disclosed herein. In some cases, a memory system, such as the memory system 110 or the memory system 210 described with reference to FIGS. 1 and 2 respectively, may operate in the first programming mode in response to an interval between two write commands exceeding a threshold duration. For example, an interval between two previous write commands may exceed a threshold interval of a programming and transfer duration (e.g., transfer write command and data duration 285 and programming duration 290, as discussed with reference to FIG. 2) and the memory system may operate in the first programming mode for a first next write operation 305 and a second next write operation 310.

In some examples, the first next write operation 305 may include a first program operation 315-a. The first program operation 315-a may program data to a first plane in a memory die. In response to the first program operation 315-a, the memory system may perform a first poll operation 320-a. In some examples, the first next write operation 305 may include SF prediction via the first SF 325-a. The memory system may predict a starting word line voltage for the next write operation (e.g., the second next write operation 310). For example, the memory system may retrieve a stored starting word line voltage from previous write operation associated with the same plane as the next write operation.

The first SF 325-a may set (e.g., precharge) a voltage of a first a word line for a second plane in response to predicting the starting word line voltage (e.g., retrieving the starting word line voltage of a previous write operation to the second plane). In some cases, the memory system may program data to the second plane via the second next write operation 310. Precharging the word line voltage for the second plane in accordance with the prediction by the first SF 325-a may reduce a programming duration of the second next write operation 310. After performing the first SF 325-a, the memory system may perform the poll operation 320-b. In some aspects, the SF 325 may correspond to a feature address (FA)=0x7F. In some examples, the memory system may perform GF prediction as part of the first next write operation 305 via the first GF 330-a. The first GF 330-a may identify a word line voltage used for the first program operation 315-a to the first plane, retrieve the word line voltage used for programming the first plane, and store the word line voltage for the next write command that writes data to the first plane. In some examples, the memory system may perform the first GF 330-a after the first program operation 315-a and ARDY=1 according to the first next write operation 305. In some aspects, the GF 330 may correspond to an FA=0x7F.

The second next write operation 310 may include a poll operation 320-c. In some cases, the memory system may perform a second program operation 315-b to program data to the second plane as part of the second next write operation 310. In some cases, a duration of the second program operation 315-b may be reduced because the first SF 325-a precharged the word line of the second plane. For example, a precharge portion of the second program operation 315-b may not be performed, thereby reducing the duration. The memory system may perform a poll 320-d in response to the second program operation 315-b. In some cases, the memory system may perform a second SF 325-b for a next write command as part of the second next write operation 310. In such cases, the memory system may perform a poll operation 320-e after performing the second SF 325-b. In some examples, the memory system may perform a second GF 330-b. The second GF 330-b may identify a word line voltage used for the second program operation 315-b to the second plane, retrieve the word line voltage used for programming the second plane, and store the word line voltage for the second plane for the next write command that writes data to the second plane.

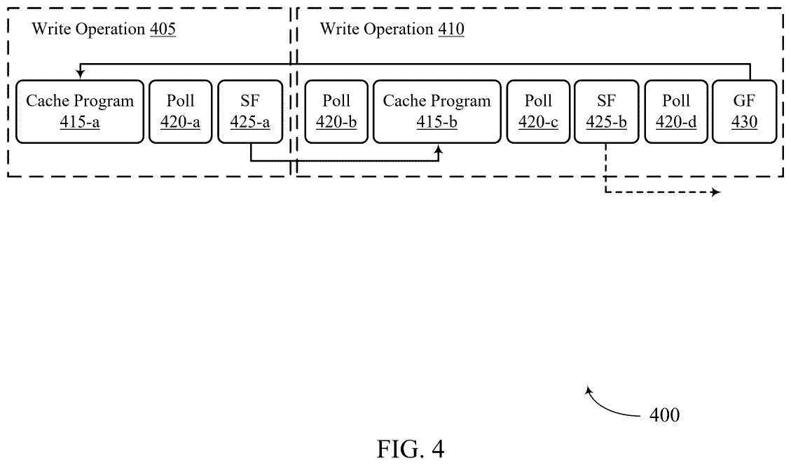

FIG. 4 shows an example of a second programming mode 400 that supports MDWLSV prediction and a self-adapting cache program for memory operations in accordance with examples as disclosed herein. In some cases, a memory system, such as the memory system 110 or the memory system 210 described with reference to FIGS. 1 and 2 respectively, may operate in the second programming mode in response to an interval duration between two write commands not exceeding a threshold duration. For example, an interval between two previous write commands may not exceed a threshold interval of a programming and transfer duration (e.g., transfer write command and data duration 285 and programming duration 290, as discussed with reference to FIG. 2) and the memory system may operate in the second programming mode for a first next write operation 405 and a second next write operation 410.

In some examples, the first next write operation 405 may include a first cache program 415-a. The first cache program 415-a may cache data for a first plane. For example, the memory system may program the first plane of a memory block in response to a previous write command. In response to performing the first cache program 415-a, the memory system may perform a poll operation 420-a. In some examples, the first next write operation 405 may include SF prediction via a first SF 425-a for a second plane. For example, the memory system may predict a starting word line voltage for the next write operation (e.g., second next write operation 410) to the second plane using a stored word line voltage used in a previous write operation to the second plane. The first SF 425-a may set (e.g., precharge) a voltage of a starting word line for the second plane in response to retrieving the starting word line voltage of the previous write operation to the second plane.

The memory system may perform the second next write operation 410, which may include a poll operation 420-b. In some cases, the memory system may perform a second cache program 415-b for the second plane according to the second next write operation 410. In some cases, the first SF 425-a may reduce a duration to complete the second cache program 415-b for the second plane. For example, the first SF 425-a may precharge a word line voltage for the second plane and a precharge portion of the second cache program 415-b may not be performed, thereby reducing the duration. The memory system may perform a poll operation 420-c in response to the second cache program 415-b as part of the second next write operation 410.

In some cases, the memory system may perform a second SF 425-b for the second next write operation 410. For example, the memory system may predict a second starting word line voltage for a next write operation for a third plane. After predicting the second starting word line voltage, the second SF 425-b may precharge the third plane, and the memory system may perform a poll operation 420-d. In some examples, the second next write operation 410 may include a GF 430. The GF 430 may identify a word line voltage used for the first cache program 415-a to the first plane, retrieve the word line voltage used for the first plane, and store the word line voltage for the first plane for the next cache program or write command that writes data to the first plane.

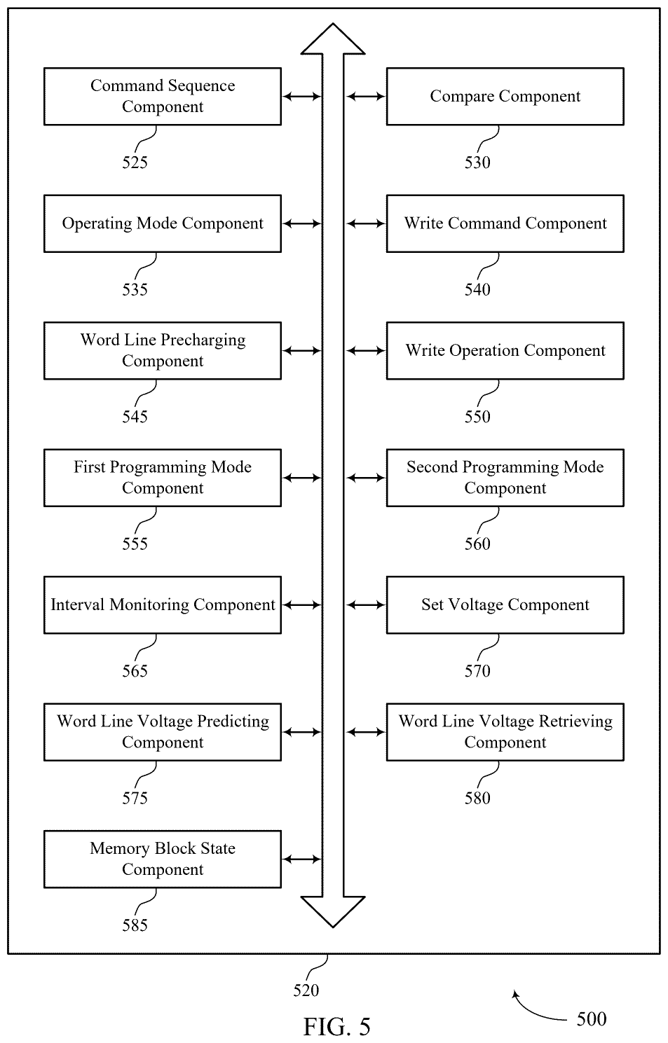

FIG. 5 shows a block diagram 500 of a memory system 520 that supports MDWLSV prediction and a self-adapting cache program for memory operations in accordance with examples as disclosed herein. The memory system 520 may be an example of aspects of a memory system as described with reference to FIGS. 1 through 4. The memory system 520, or various components thereof, may be an example of means for performing various aspects of MDWLSV prediction and a self-adapting cache program for memory operations as described herein. For example, the memory system 520 may include a command sequence component 525, a compare component 530, an operating mode component 535, a write command component 540, a word line precharging component 545, a write operation component 550, a first programming mode component 555, a second programming mode component 560, an interval monitoring component 565, a set voltage component 570, a word line voltage predicting component 575, a word line voltage retrieving component 580, a memory block state component 585, or any combination thereof. Each of these components, or components of subcomponents thereof (e.g., one or more processors, one or more memories), may communicate, directly or indirectly, with one another (e.g., via one or more buses).

The command sequence component 525 may be configured as or otherwise support a means for receiving a sequence of write commands for a memory block of a memory device. The compare component 530 may be configured as or otherwise support a means for comparing a write command interval with a threshold interval, the write command interval corresponding to a time period between a first write command of the sequence of write commands and a second write command of the sequence of write commands, the second write command consecutive to the first write command in the sequence of write commands. The operating mode component 535 may be configured as or otherwise support a means for operating the memory device in one of a first programming mode or a second programming mode based at least in part on comparing the write command interval with the threshold interval, where the first programming mode is associated with prediction of a starting word line voltage for a next write operation corresponding to a next write command and a retrieval of the starting word line voltage based at least in part on a previous write command, and the second programming mode is associated with prediction of the starting word line voltage for the next write operation corresponding to the next write command.

In some examples, the first programming mode component 555 may be configured as or otherwise support a means for operating the memory device in the first programming mode based at least in part on the write command interval exceeding the threshold interval.

In some examples, to support operating in the first programming mode, the first programming mode component 555 may be configured as or otherwise support a means for storing, in accordance with the first programming mode, the starting word line voltage based at least in part on the retrieval of the starting word line voltage from a previous write operation associated with the previous write command. In some examples, to support operating in the first programming mode, the first programming mode component 555 may be configured as or otherwise support a means for predicting, based at least in part on storing the starting word line voltage, the starting word line voltage for the next write operation corresponding to the next write command, the next write operation for a first plane of the memory block. In some examples, to support operating in the first programming mode, the first programming mode component 555 may be configured as or otherwise support a means for setting a voltage of a first word line associated with the first plane of the memory block to the starting word line voltage based at least in part on predicting the starting word line voltage. In some examples, to support operating in the first programming mode, the first programming mode component 555 may be configured as or otherwise support a means for programming, based at least in part on the next write operation associated with the next write command, the first plane of the memory block in accordance with the starting word line voltage and the first programming mode.

In some examples, the word line voltage retrieving component 580 may be configured as or otherwise support a means for retrieving, from the previous write command in accordance with the first programming mode, the starting word line voltage, where predicting the starting word line voltage is based at least in part on retrieving the starting word line voltage and a ready state of the memory block.

In some examples, the second programming mode component 560 may be configured as or otherwise support a means for operating the memory device in the second programming mode based at least in part on the write command interval being less than the threshold interval.

In some examples, to support operating in the second programming mode, the second programming mode component 560 may be configured as or otherwise support a means for programming, based at least in part on the previous write command, a first plane of the memory block in accordance with the second programming mode. In some examples, to support operating in the second programming mode, the second programming mode component 560 may be configured as or otherwise support a means for predicting the starting word line voltage for the next write operation associated with the next write command, the next write operation associated with a second plane of the memory block. In some examples, to support operating in the second programming mode, the second programming mode component 560 may be configured as or otherwise support a means for setting a voltage of a first word line associated with the second plane of the memory block to the starting word line voltage based at least in part on predicting the starting word line voltage. In some examples, to support operating in the second programming mode, the second programming mode component 560 may be configured as or otherwise support a means for programming, based at least in part on the next write operation associated with the next write command, the second plane of the memory block in accordance with the starting word line voltage and the second programming mode.

In some examples, the second programming mode component 560 may be configured as or otherwise support a means for predicting a second starting word line voltage for a second write operation associated with the second write command, the second write operation associated with a third plane of the memory block. In some examples, the second programming mode component 560 may be configured as or otherwise support a means for setting a second voltage of a second word line associated with the second plane of the memory block to the second starting word line voltage based at least in part on predicting the second starting word line voltage.

In some examples, the interval monitoring component 565 may be configured as or otherwise support a means for monitoring a respective write command interval between each pair of two consecutive write commands of the sequence of write commands, where comparing the write command interval with the threshold interval is based at least in part on monitoring the respective write command intervals.

In some examples, the set voltage component 570 may be configured as or otherwise support a means for setting, in accordance with a set feature of the first programming mode or the second programming mode, a voltage of a word line associated with the next write operation to the starting word line voltage based at least in part on predicting the starting word line voltage. In some examples, the write operation component 550 may be configured as or otherwise support a means for performing, after setting the voltage of the word line to the starting word line voltage, the next write operation in accordance with the first programming mode or the second programming mode. In some examples, the first programming mode includes a non-cache programming mode and the second programming mode includes a cache programming mode.

In some examples, the threshold interval is based at least in part on a queue depth associated with the sequence of write commands. In some examples, the threshold interval is based at least in part on a program duration and a write command transfer duration.

In some examples, the prediction of the starting word line voltage for the next write operation includes an MDWLSV. In some examples, the next write command is associated with a first plane or a first memory block that is different than a second plane or a second memory block associated with the previous write command.

The write command component 540 may be configured as or otherwise support a means for receiving a first write command that indicates first data for a memory block of a memory device. In some examples, the write command component 540 may be configured as or otherwise support a means for receiving a second write command that indicates second data for the memory block. The word line precharging component 545 may be configured as or otherwise support a means for precharging, before completing a first next write operation to write the first data to the memory block based at least in part on the first write command, at least one word line of the memory block to a first voltage for a second write operation associated with the second write command for the memory block. The write operation component 550 may be configured as or otherwise support a means for performing, based at least in part on precharging the at least one word line and based at least in part on the second write command, the second write operation to write the second data to the memory block, where the first next write operation and the second write operation are in accordance with a manual write mode of the memory device.

In some examples, the word line voltage predicting component 575 may be configured as or otherwise support a means for predicting, based at least in part on the first write command, a starting word line voltage associated with the second write command and a second plane of the memory block, where the first voltage is equal to the starting word line voltage, and where precharging the at least one word line is based at least in part on predicting the starting word line voltage.

In some examples, the word line precharging component 545 may be configured as or otherwise support a means for retrieving, based at least in part on the first write command, a starting word line voltage from a cache, the starting word line voltage associated with a previous write operation, where precharging the at least one word line is based at least in part on retrieving the starting word line voltage.

In some examples, the memory block state component 585 may be configured as or otherwise support a means for determining whether a state of the memory block satisfies a condition, where retrieving the starting word line voltage is based at least in part on the determining that the state of the memory block satisfies the condition.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

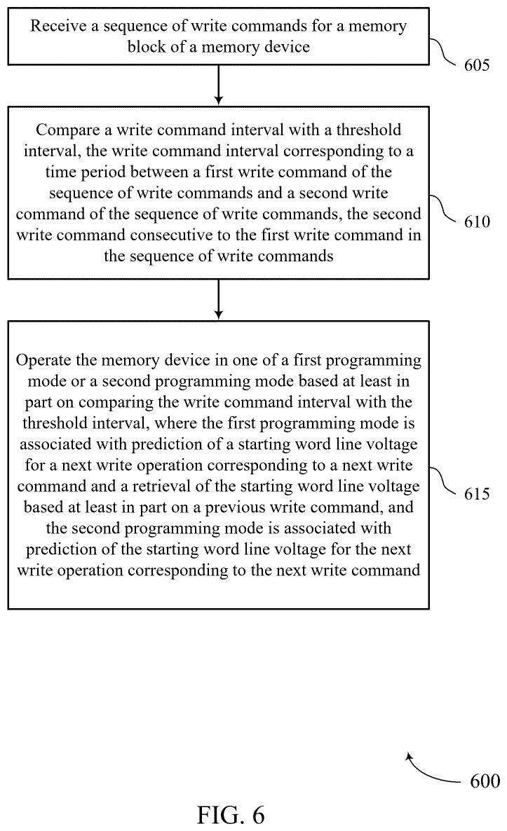

FIG. 6 shows a flowchart illustrating a method 600 that supports MDWLSV prediction and a self-adapting cache program for memory operations in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include receiving a sequence of write commands for a memory block of a memory device. In some examples, aspects of the operations of 605 may be performed by a command sequence component 525 as described with reference to FIG. 5.

At 610, the method may include comparing a write command interval with a threshold interval, the write command interval corresponding to a time period between a first write command of the sequence of write commands and a second write command of the sequence of write commands, the second write command consecutive to the first write command in the sequence of write commands. In some examples, aspects of the operations of 610 may be performed by a compare component 530 as described with reference to FIG. 5.

At 615, the method may include operating the memory device in one of a first programming mode or a second programming mode based at least in part on comparing the write command interval with the threshold interval, where the first programming mode is associated with prediction of a starting word line voltage for a next write operation corresponding to a next write command and a retrieval of the starting word line voltage based at least in part on a previous write command, and the second programming mode is associated with prediction of the starting word line voltage for the next write operation corresponding to the next write command. In some examples, aspects of the operations of 615 may be performed by an operating mode component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a sequence of write commands for a memory block of a memory device; comparing a write command interval with a threshold interval, the write command interval corresponding to a time period between a first write command of the sequence of write commands and a second write command of the sequence of write commands, the second write command consecutive to the first write command in the sequence of write commands; and operating the memory device in one of a first programming mode or a second programming mode based at least in part on comparing the write command interval with the threshold interval, where the first programming mode is associated with prediction of a starting word line voltage for a next write operation corresponding to a next write command and a retrieval of the starting word line voltage based at least in part on a previous write command, and the second programming mode is associated with prediction of the starting word line voltage for the next write operation corresponding to the next write command.

Aspect 2: The method, apparatus, or non-transitory computer-readable medium of aspect 1, further including operations, features, circuitry, logic, means, or instructions, or any combination thereof for operating the memory device in the first programming mode based at least in part on the write command interval exceeding the threshold interval.

Aspect 3: The method, apparatus, or non-transitory computer-readable medium of aspect 2, where operating in the first programming mode includes operations, features, circuitry, logic, means, or instructions, or any combination thereof for storing, in accordance with the first programming mode, the starting word line voltage based at least in part on the retrieval of the starting word line voltage from a previous write operation associated with the previous write command; predicting, based at least in part on storing the starting word line voltage, the starting word line voltage for the next write operation corresponding to the next write command, the next write operation for a first plane of the memory block; setting a voltage of a first word line associated with the first plane of the memory block to the starting word line voltage based at least in part on predicting the starting word line voltage; and programming, based at least in part on the next write operation associated with the next write command, the first plane of the memory block in accordance with the starting word line voltage and the first programming mode.

Aspect 4: The method, apparatus, or non-transitory computer-readable medium of any of aspects 2 through 3, further including operations, features, circuitry, logic, means, or instructions, or any combination thereof for retrieving, from the previous write command in accordance with the first programming mode, the starting word line voltage, where predicting the starting word line voltage is based at least in part on retrieving the starting word line voltage and a ready state of the memory block.

Aspect 5: The method, apparatus, or non-transitory computer-readable medium of aspect 1, further including operations, features, circuitry, logic, means, or instructions, or any combination thereof for operating the memory device in the second programming mode based at least in part on the write command interval being less than the threshold interval.

Aspect 6: The method, apparatus, or non-transitory computer-readable medium of aspect 5, where operating in the second programming mode includes operations, features, circuitry, logic, means, or instructions, or any combination thereof for programming, based at least in part on the previous write command, a first plane of the memory block in accordance with the second programming mode; predicting the starting word line voltage for the next write operation associated with the next write command, the next write operation associated with a second plane of the memory block; setting a voltage of a first word line associated with the second plane of the memory block to the starting word line voltage based at least in part on predicting the starting word line voltage; and programming, based at least in part on the next write operation associated with the next write command, the second plane of the memory block in accordance with the starting word line voltage and the second programming mode.

Aspect 7: The method, apparatus, or non-transitory computer-readable medium of aspect 6, further including operations, features, circuitry, logic, means, or instructions, or any combination thereof for predicting a second starting word line voltage for a second write operation associated with the second write command, the second write operation associated with a third plane of the memory block and setting a second voltage of a second word line associated with the second plane of the memory block to the second starting word line voltage based at least in part on predicting the second starting word line voltage.

Aspect 8: The method, apparatus, or non-transitory computer-readable medium of any of aspects 1 through 7, further including operations, features, circuitry, logic, means, or instructions, or any combination thereof for monitoring a respective write command interval between each pair of two consecutive write commands of the sequence of write commands, where comparing the write command interval with the threshold interval is based at least in part on monitoring the respective write command intervals.

Aspect 9: The method, apparatus, or non-transitory computer-readable medium of any of aspects 1 through 8, further including operations, features, circuitry, logic, means, or instructions, or any combination thereof for setting, in accordance with a set feature of the first programming mode or the second programming mode, a voltage of a word line associated with the next write operation to the starting word line voltage based at least in part on predicting the starting word line voltage and performing, after setting the voltage of the word line to the starting word line voltage, the next write operation in accordance with the first programming mode or the second programming mode.

Aspect 10: The method, apparatus, or non-transitory computer-readable medium of any of aspects 1 through 9, where the first programming mode includes a non-cache programming mode and the second programming mode includes a cache programming mode.

Aspect 11: The method, apparatus, or non-transitory computer-readable medium of any of aspects 1 through 10, where the threshold interval is based at least in part on a queue depth associated with the sequence of write commands.

Aspect 12: The method, apparatus, or non-transitory computer-readable medium of any of aspects 1 through 11, where the threshold interval is based at least in part on a program duration and a write command transfer duration.

Aspect 13: The method, apparatus, or non-transitory computer-readable medium of any of aspects 1 through 12, where the prediction of the starting word line voltage for the next write operation includes an MDWLSV prediction.

Aspect 14: The method, apparatus, or non-transitory computer-readable medium of any of aspects 1 through 13, where the next write command is associated with a first plane or a first memory block that is different than a second plane or a second memory block associated with the previous write command.

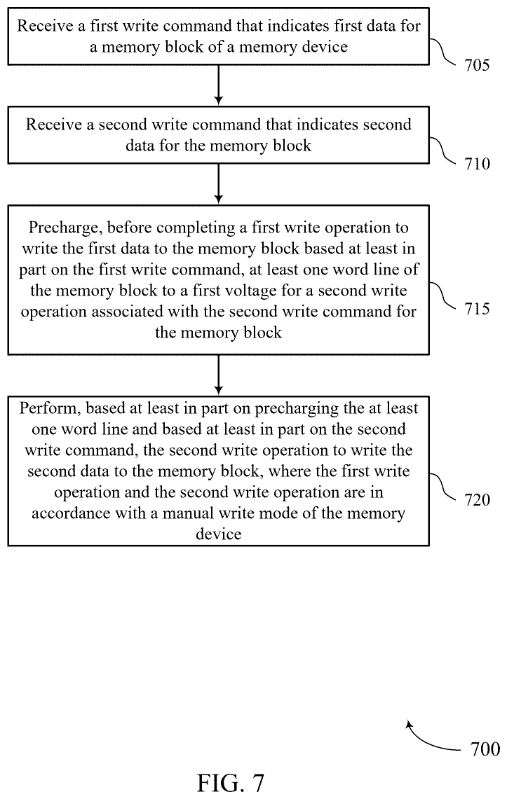

FIG. 7 shows a flowchart illustrating a method 700 that supports MDWLSV prediction and a self-adapting cache program for memory operations in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include receiving a first write command that indicates first data for a memory block of a memory device. In some examples, aspects of the operations of 705 may be performed by a write command component 540 as described with reference to FIG. 5. At 710, the method may include receiving a second write command that indicates second data for the memory block. In some examples, aspects of the operations of 710 may be performed by a write command component 540 as described with reference to FIG. 5.

At 715, the method may include precharging, before completing a first next write operation to write the first data to the memory block based at least in part on the first write command, at least one word line of the memory block to a first voltage for a second write operation associated with the second write command for the memory block. In some examples, aspects of the operations of 715 may be performed by a word line precharging component 545 as described with reference to FIG. 5.

At 720, the method may include performing, based at least in part on precharging the at least one word line and based at least in part on the second write command, the second write operation to write the second data to the memory block, where the first next write operation and the second write operation are in accordance with a manual write mode of the memory device. In some examples, aspects of the operations of 720 may be performed by a write operation component 550 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 15: A method, apparatus, or non-transitory computer-readable medium including operations, features, circuitry, logic, means, or instructions, or any combination thereof for receiving a first write command that indicates first data for a memory block of a memory device; receiving a second write command that indicates second data for the memory block; precharging, before completing a first next write operation to write the first data to the memory block based at least in part on the first write command, at least one word line of the memory block to a first voltage for a second write operation associated with the second write command for the memory block; and performing, based at least in part on precharging the at least one word line and based at least in part on the second write command, the second write operation to write the second data to the memory block, where the first next write operation and the second write operation are in accordance with a manual write mode of the memory device.

Aspect 16: The method, apparatus, or non-transitory computer-readable medium of aspect 15, further including operations, features, circuitry, logic, means, or instructions, or any combination thereof for predicting, based at least in part on the first write command, a starting word line voltage associated with the second write command and a second plane of the memory block, where the first voltage is equal to the starting word line voltage, and where precharging the at least one word line is based at least in part on predicting the starting word line voltage.

Aspect 17: The method, apparatus, or non-transitory computer-readable medium of any of aspects 15 through 16, further including operations, features, circuitry, logic, means, or instructions, or any combination thereof for retrieving, based at least in part on the first write command, a starting word line voltage from a cache, the starting word line voltage associated with a previous write operation, where precharging the at least one word line is based at least in part on retrieving the starting word line voltage.

Aspect 18: The method, apparatus, or non-transitory computer-readable medium of aspect 17, further including operations, features, circuitry, logic, means, or instructions, or any combination thereof for determining whether a state of the memory block satisfies a condition, where retrieving the starting word line voltage is based at least in part on the determining that the state of the memory block satisfies the condition.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor.

Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
processing circuitry associated with one or more memory devices and configured to cause the apparatus to:
receive a sequence of write commands for a memory block of a memory device;
compare a write command interval with a threshold interval, the write command interval corresponding to a time period between a first write command of the sequence of write commands and a second write command of the sequence of write commands, the second write command consecutive to the first write command in the sequence of write commands; and
operate the memory device in one of a first programming mode or a second programming mode based at least in part on comparing the write command interval with the threshold interval, wherein the first programming mode is associated with prediction of a starting word line voltage for a next write operation corresponding to a next write command and a retrieval of the starting word line voltage based at least in part on a previous write command, and the second programming mode is associated with prediction of the starting word line voltage for the next write operation corresponding to the next write command.

2. The apparatus of claim 1, wherein the processing circuitry is further configured to cause the apparatus to:
operate the memory device in the first programming mode based at least in part on the write command interval exceeding the threshold interval.

3. The apparatus of claim 2, wherein, to operate in the first programming mode, the processing circuitry is configured to cause the apparatus to:
store, in accordance with the first programming mode, the starting word line voltage based at least in part on the retrieval of the starting word line voltage from a previous write operation associated with the previous write command;
predict, based at least in part on storing the starting word line voltage, the starting word line voltage for the next write operation corresponding to the next write command, the next write operation for a first plane of the memory block;
set a voltage of a first word line associated with the first plane of the memory block to the starting word line voltage based at least in part on predicting the starting word line voltage; and
program, based at least in part on the next write operation associated with the next write command, the first plane of the memory block in accordance with the starting word line voltage and the first programming mode.

4. The apparatus of claim 2, wherein the processing circuitry is further configured to cause the apparatus to:
retrieve, from the previous write command in accordance with the first programming mode, the starting word line voltage, wherein predicting the starting word line voltage is based at least in part on retrieving the starting word line voltage and a ready state of the memory block.

5. The apparatus of claim 1, wherein the processing circuitry is further configured to cause the apparatus to:
operate the memory device in the second programming mode based at least in part on the write command interval being less than the threshold interval.

6. The apparatus of claim 5, wherein, to operate in the second programming mode, the processing circuitry is configured to cause the apparatus to:
program, based at least in part on the previous write command, a first plane of the memory block in accordance with the second programming mode;
predict the starting word line voltage for the next write operation associated with the next write command, the next write operation associated with a second plane of the memory block;
set a voltage of a first word line associated with the second plane of the memory block to the starting word line voltage based at least in part on predicting the starting word line voltage; and
program, based at least in part on the next write operation associated with the next write command, the second plane of the memory block in accordance with the starting word line voltage and the second programming mode.

7. The apparatus of claim 6, wherein the processing circuitry is further configured to cause the apparatus to:
predict a second starting word line voltage for a second write operation associated with the second write command, the second write operation associated with a third plane of the memory block; and
set a second voltage of a second word line associated with the second plane of the memory block to the second starting word line voltage based at least in part on predicting the second starting word line voltage.

8. The apparatus of claim 1, wherein the processing circuitry is further configured to cause the apparatus to:
monitor a respective write command interval between each pair of two consecutive write commands of the sequence of write commands, wherein comparing the write command interval with the threshold interval is based at least in part on monitoring the respective write command intervals.

9. The apparatus of claim 1, wherein the processing circuitry is further configured to cause the apparatus to:
set, in accordance with a set feature of the first programming mode or the second programming mode, a voltage of a word line associated with the next write operation to the starting word line voltage based at least in part on predicting the starting word line voltage; and
perform, after setting the voltage of the word line to the starting word line voltage, the next write operation in accordance with the first programming mode or the second programming mode.

10. The apparatus of claim 1, wherein the first programming mode comprises a non-cache programming mode and the second programming mode comprises a cache programming mode.

11. The apparatus of claim 1, wherein the threshold interval is based at least in part on a queue depth associated with the sequence of write commands.

12. The apparatus of claim 1, wherein the threshold interval is based at least in part on a program duration and a write command transfer duration.

13. The apparatus of claim 1, wherein the prediction of the starting word line voltage for the next write operation comprises a manual dynamic word line start voltage (MDWLSV) prediction.

14. The apparatus of claim 1, wherein the next write command is associated with a first plane or a first memory block that is different than a second plane or a second memory block associated with the previous write command.

15. An apparatus, comprising:
processing circuitry associated with one or more memory devices and configured to cause the apparatus to:
receive a first write command that indicates first data for a memory block of a memory device;
receive a second write command that indicates second data for the memory block;
precharge, before completing a first next write operation to write the first data to the memory block based at least in part on the first write command, at least one word line of the memory block to a first voltage for a second write operation associated with the second write command for the memory block; and
perform, based at least in part on precharging the at least one word line and based at least in part on the second write command, the second write operation to write the second data to the memory block, wherein the first next write operation and the second write operation are in accordance with a manual write mode of the memory device.

16. The apparatus of claim 15, wherein the processing circuitry is further configured to cause the apparatus to:
predict, based at least in part on the first write command, a starting word line voltage associated with the second write command and a second plane of the memory block, wherein the first voltage is equal to the starting word line voltage, and wherein precharging the at least one word line is based at least in part on predicting the starting word line voltage.

17. The apparatus of claim 15, wherein the processing circuitry is further configured to cause the apparatus to:
retrieve, based at least in part on the first write command, a starting word line voltage from a cache, the starting word line voltage associated with a previous write operation, wherein precharging the at least one word line is based at least in part on retrieving the starting word line voltage.

18. The apparatus of claim 17, wherein the processing circuitry is further configured to cause the apparatus to:
determine whether a state of the memory block satisfies a condition, wherein retrieving the starting word line voltage is based at least in part on the determining that the state of the memory block satisfies the condition.

19. A non-transitory computer-readable medium storing code, the code comprising instructions executable by one or more processors to:
receive a sequence of write commands for a memory block of a memory device;
compare a write command interval with a threshold interval, the write command interval corresponding to a time period between a first write command of the sequence of write commands and a second write command of the sequence of write commands, the second write command consecutive to the first write command in the sequence of write commands; and
operate the memory device in one of a first programming mode or a second programming mode based at least in part on comparing the write command interval with the threshold interval, wherein the first programming mode is associated with prediction of a starting word line voltage for a next write operation corresponding to a next write command and a retrieval of the starting word line voltage based at least in part on a previous write command, and the second programming mode is associated with prediction of the starting word line voltage for the next write operation corresponding to the next write command.

20. The non-transitory computer-readable medium of claim 19, wherein the instructions are further executable by the one or more processors to:
set, in accordance with a set feature of the first programming mode or the second programming mode, a voltage of a word line associated with the next write operation to the starting word line voltage based at least in part on predicting the starting word line voltage; and
perform, after setting the voltage of the word line to the starting word line voltage, the next write operation in accordance with the first programming mode or the second programming mode.
